(19) United States
(12) Patent Application Publication
(10) Pub. No.: US 2026/0123010 A1
(43) Pub. Date: Apr. 30, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Pei-Hsun Kao, Kaohsiung City (TW); Hsin-Chieh Lin, Kaohsiung City (TW); Chun-Wei Yu, Tainan City (TW); Shao-Wei Wang, Taichung City (TW)

(73) Assignee: UNITED MICROELECTRONICS CORP., Hsin-Chu City (TW)

(21) Appl. No.: 18/984,978

(22) Filed: Dec. 17, 2024

(30) Foreign Application Priority Data
Oct. 24, 2024 (TW) 113140517

(51) Int. Cl. H10D 64/27; H01L 21/02; H01L 21/311; H10D 30/68

(52) U.S. Cl. CPC H10D 64/516; H10D 30/6892; H10D 64/518; H10P 14/6528; H10P 50/283

(57) ABSTRACT

A semiconductor device includes a doped region, a first gate and an insulating structure. The doped region is disposed in a substrate. The first gate extends along a first direction on the doped region. The insulating structure is disposed at a side of the first gate along a second direction. The insulating structure includes a first curve side surface directly contacting the first gate, and the first curve side surface has an inclined angle less than 45 degrees.

### BACKGROUND OF THE INVENTION

### 1. Field of the Invention

The present disclosure relates to the field of semiconductor devices, and more particularly, to a semiconductor device applicable to a memory and a method for fabricating the same.

### 2. Description of the Prior Art

With the vigorous development of cutting-edge technologies, such as the Internet of Things, edge computing and artificial intelligence, capabilities for processing huge information are required, and memory cells play an indispensable role. When the information that needs to be processed is huge, the required memory cells also need to increase accordingly. Even electronic products only with basic functions also include millions of memory cells. Therefore, how to improve the properties of memory cells is a goal of relevant industries.

### SUMMARY OF THE INVENTION

According to one aspect of the present disclosure, a semiconductor device includes a doped region, a first gate and an insulating structure. The doped region is disposed in a substrate. The first gate extends along a first direction on the doped region. The insulating structure is disposed at a side of the first gate along a second direction. The insulating structure includes a first curve side surface directly contacting the first gate, and the first curve side surface has an inclined angle less than 45 degrees.

According to another aspect of the present disclosure, a method for fabricating a semiconductor device includes steps as follows. An insulating structure is formed in a substrate, wherein the substrate includes a portion disposed adjacent to the insulating structure. A doped region is formed in the portion of the substrate. A portion of the insulating structure is removed to form a first curve side surface. A first gate extending along a first direction is formed on the doped region. The insulating structure is disposed at a side of the first gate along a second direction. The first curve side surface directly contacts the first gate, and the first curve side surface has an inclined angle less than 45 degrees.

Compared with the prior art, in the present disclosure, a portion of the insulating structure is removed by an etching process, so that the insulating structure disposed at a side of the first gate is configured with a first curve side surface. Moreover, the solutions and parameters of the etching process and the subsequent cleaning process are controlled to allow the first curve side surface to have a smaller inclined angle, and preferably to allow the gate insulating layer formed later to have a thicker thickness and a rounding corner, which is beneficial to enhance the breakdown voltage, and improve the properties of the semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view showing a step of a method for fabricating a semiconductor device according to an embodiment of the present disclosure.

FIG. 2 shows schematic cross-sectional views taken along line A-A′ and line B-B′ in FIG. 1.

FIG. 3, FIG. 4, FIG. 5, FIG. 6, FIG. 7 and FIG. 8 are schematic cross-sectional views showing steps of a method for fabricating a semiconductor device according to an embodiment of the present disclosure.

FIG. 9 is a schematic top view showing a step of a method for fabricating a semiconductor device according to an embodiment of the present disclosure.

FIG. 10 shows schematic cross-sectional views taken along line A-A′ and line B-B′ in FIG. 9.

FIG. 11 is an enlarged view of a portion X of the semiconductor device shown in FIG. 10.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

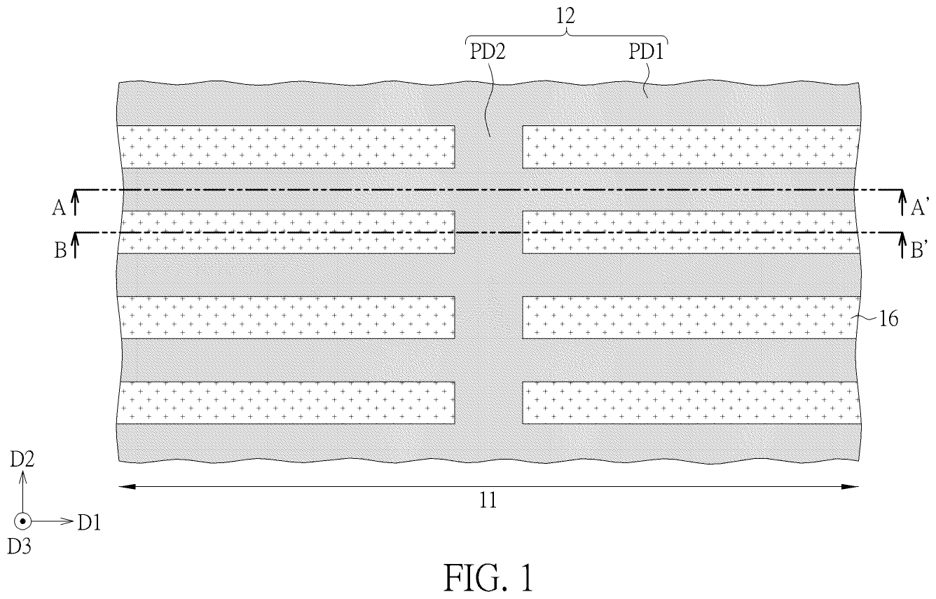

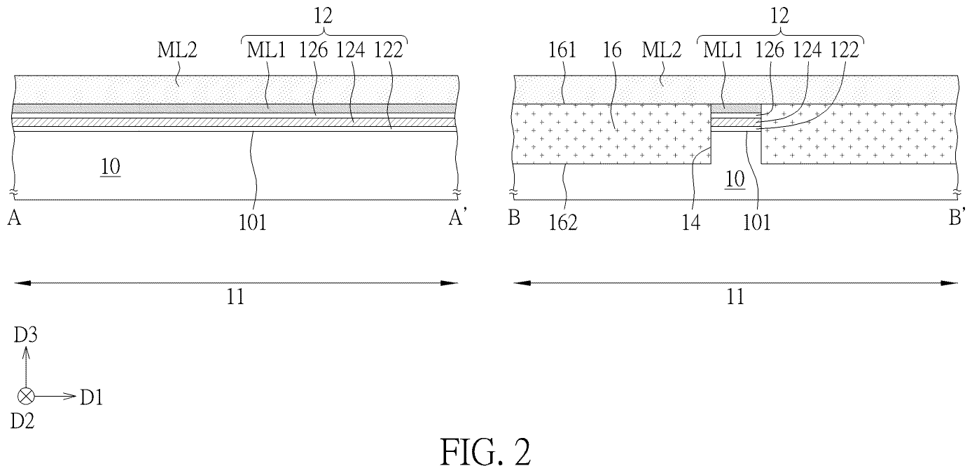

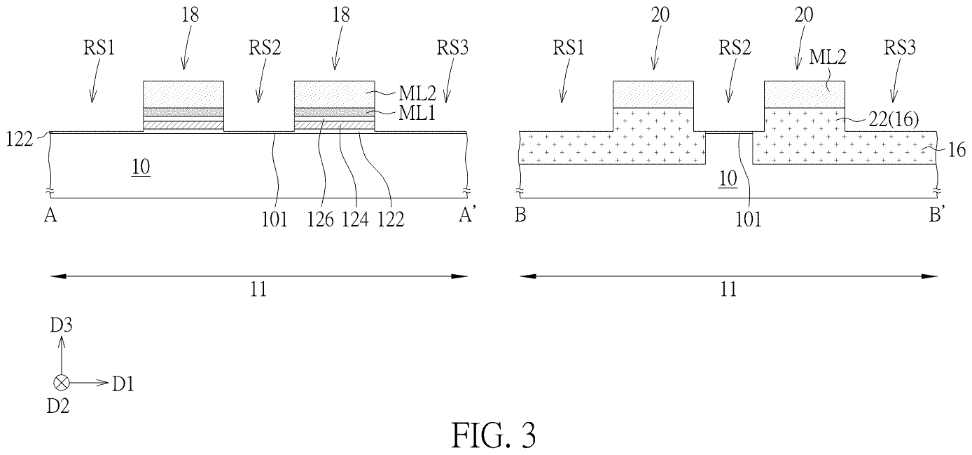

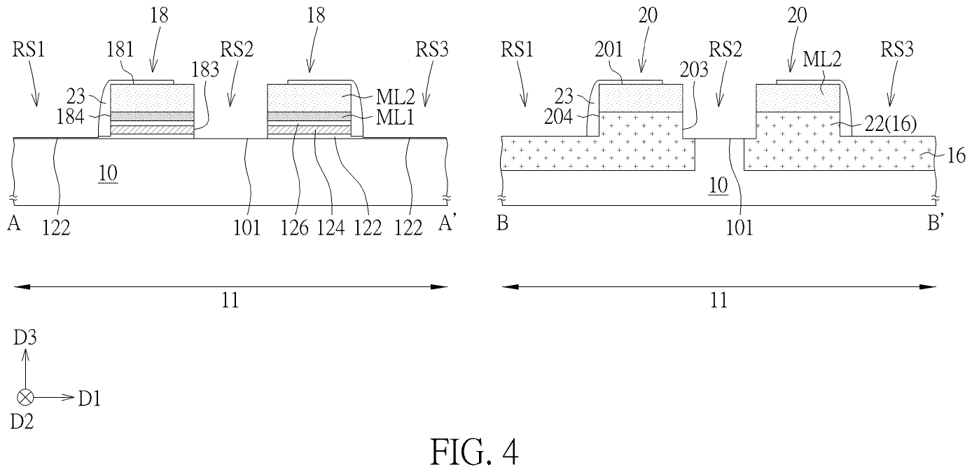

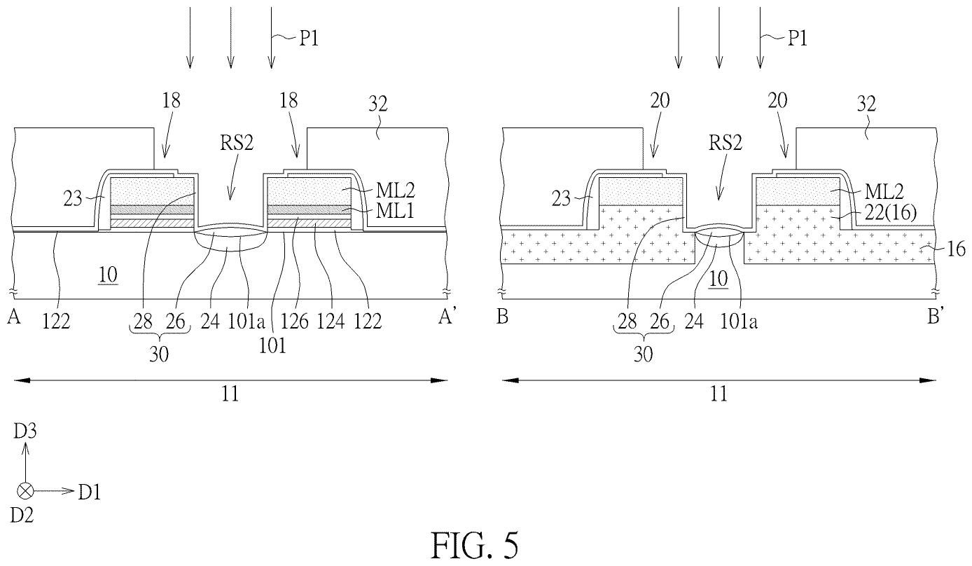

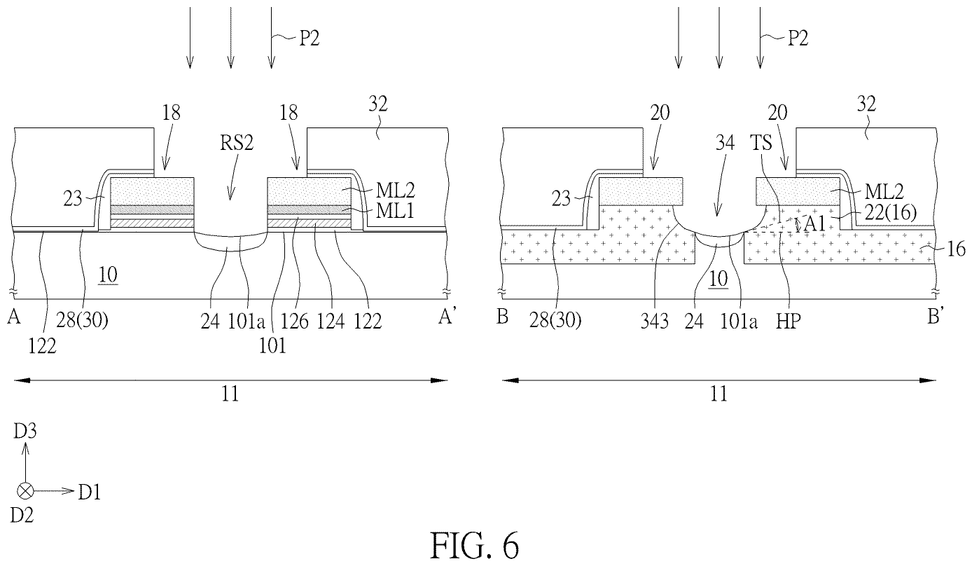

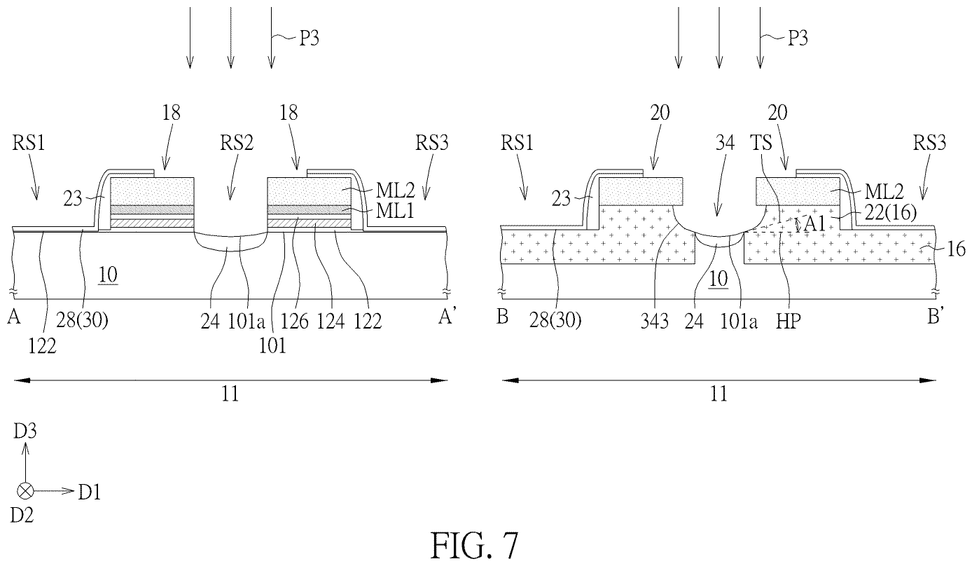

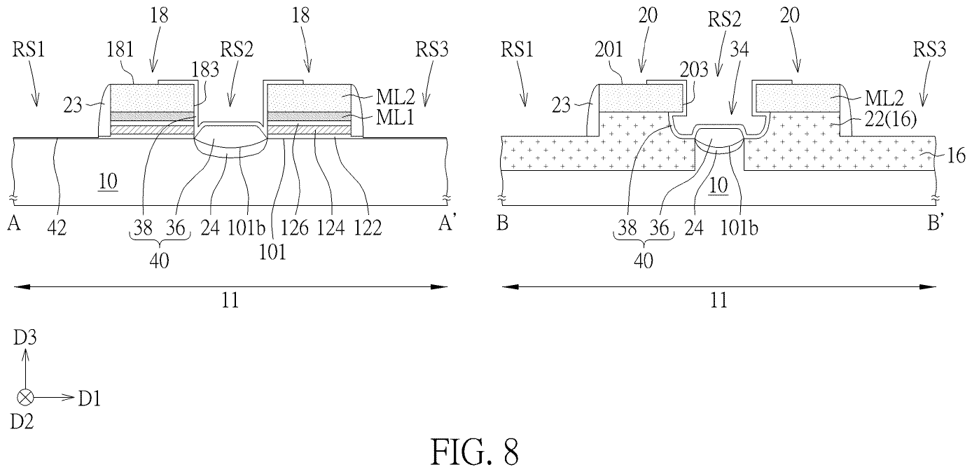

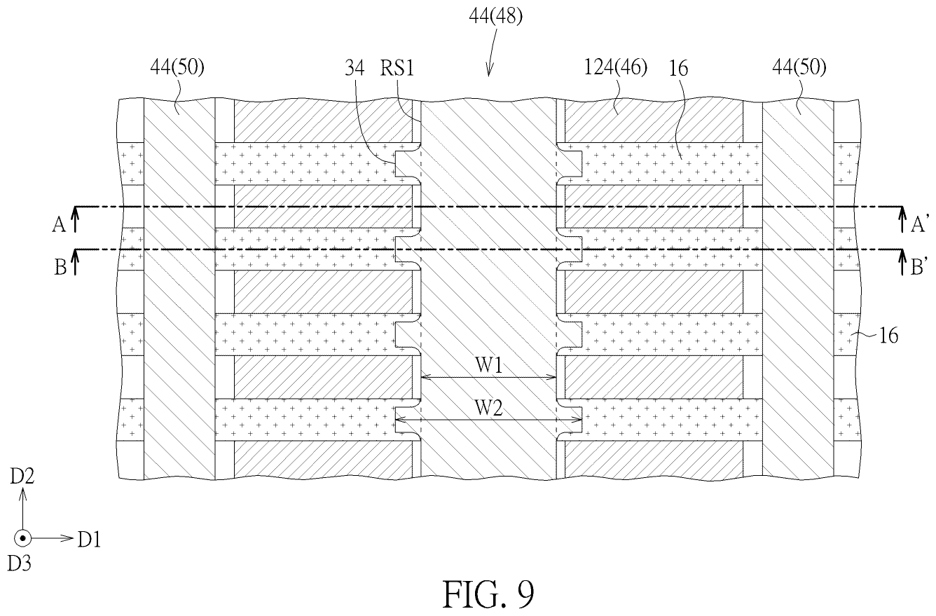

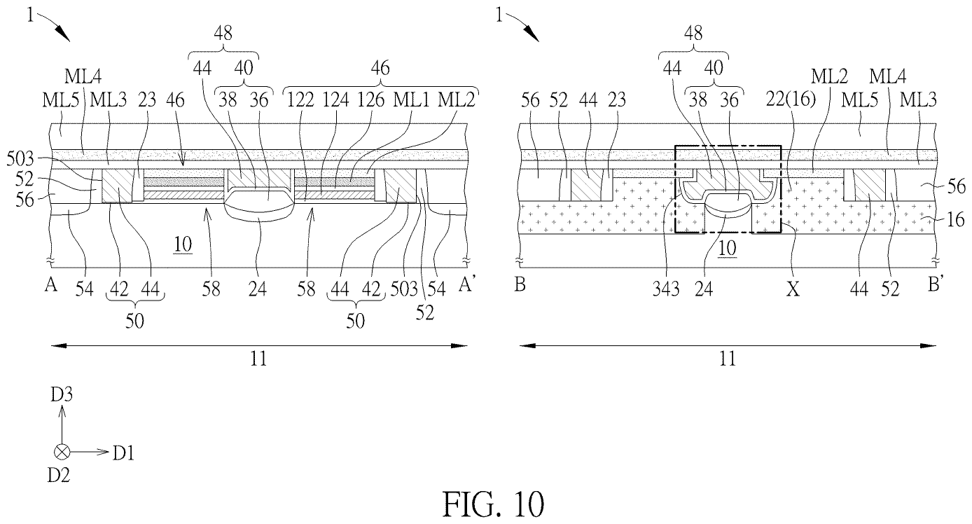

Please refer to FIG. 1 to FIG. 10. FIG. 1 is a schematic top view showing a step of a method for fabricating a semiconductor device according to an embodiment of the present disclosure. FIG. 2 shows schematic cross-sectional views taken along line A-A′ and line B-B′ in FIG. 1. FIG. 3 to FIG. 8 are schematic cross-sectional views showing steps of a method for fabricating a semiconductor device according to an embodiment of the present disclosure. FIG. 9 is a schematic top view showing a step of a method for fabricating a semiconductor device according to an embodiment of the present disclosure. FIG. 10 shows schematic cross-sectional views taken along line A-A′ and line B-B′ in FIG. 9. For the sake of conciseness, some elements may be omitted in each of the drawings. For example, the mask layer ML2 is omitted in FIG. 1 compared with FIG. 2.

As shown in FIG. 1 and FIG. 2, a substrate 10 may be firstly provided. The substrate 10, for example, may be a silicon substrate, an epitaxial silicon substrate, a silicon carbide substrate or a silicon on insulator (SOI) substrate. The substrate 10 may define a device region 11 and at least one other region (not shown) disposed adjacent to the device region 11. For example, the device region 11 may be a memory region, which may be disposed with a memory unit, such as an embedded flash memory or an embedded super-flash memory. The other region may be a logical region or a peripheral region, but not limited thereto.

Next, a gate material stack 12 is formed to blanketly cover the substrate 10. The gate material stack 12 includes a gate insulating layer 122, a charge storage layer 124, a blocking insulating layer 126 and a mask layer ML1 from bottom to top. The material of the gate insulating layer 122 may include dielectric materials, such as silicon oxide, silicon nitride (Si₃N₄), silicon oxynitride (SiON), high dielectric constant materials, other non-conductive materials, or a combination thereof. The high dielectric constant (high-k) materials may include, for example, dielectric materials with a dielectric constant greater than 10. The material of the charge storage layer 124 may include a conductor for storing charges such as doped polysilicon, or may include a non-conductive material for capturing charges such as silicon nitride (SiN) to form a charge trapping layer to store charges. The material of the blocking insulating layer 126 may include dielectric materials, such as silicon oxide, silicon nitride, silicon oxynitride, high-k materials, other non-conductive materials, or a combination thereof. The high-k material may include, for example, dielectric materials with a dielectric constant greater than 10. The material of the gate insulating layer 122 may be identical to or different from the material of the blocking insulating layer 126. The material of the mask layer ML1 may include silicon oxide, silicon nitride, silicon carbide and/or silicon oxynitride. However, the present disclosure is not limited thereto. The material of each film layer of the gate material stack 12 may be flexibly adjusted according to actual needs.

Next, insulating structures 16 are formed in the gate material stack 12 and the substrate 10. For example, semiconductor processes, such as lithography process and etching process, may be performed to remove a portion of the mask layer ML1 to pattern the mask layer ML1, and then an etching process is performed with the patterned mask layer ML1 as a mask to remove a portion of the blocking insulating layer 126 exposed from the mask layer ML1 and the charge storage layer 124, the gate insulating layer 122 and the substrate 10 below the portion of the blocking insulating layer 126 to form a recess 14. Next, a dielectric material is filled into the recess 14 and a planarization process is performed to allow the top surface of the dielectric material to be aligned with the top surface of the mask layer ML1, so as to complete the fabrication of the insulating structures 16. Next, an ion implantation process may be performed to form a well region (not shown) in the substrate 10. The conductivity type of the well region may be determined by the dopants thereof. For example, the well region may be doped with N-type impurities, such as arsenic, phosphorus, etc., and thus has a first conductivity type. As another example, the well region may be doped with P-type impurities, such as boron, indium, etc., and thus has a second conductivity type.

As shown in FIG. 2, the bottom surface 162 of the insulating structure 16 is lower than the top surface 101 of the substrate 10, and the top surface 161 of the insulating structure 16 is higher than the top surface 101 of the substrate 10. Afterward, a mask layer ML2 may be optionally formed to blanketly cover the gate material stack 12 and the insulating structures 16 on the substrate 10, so as to obtain the semiconductor device shown in FIG. 2. The mask layer ML2, for example, may be configured to allow the top surface of the device region 11 to be aligned with the top surfaces of other regions (not shown). The material of the insulating structure 16 may include dielectric materials. The dielectric materials may include oxides, such as silicon oxide. The material of the mask layer ML2 may include silicon oxide, silicon nitride, silicon carbide and/or silicon oxynitride, but not limited thereto.

As shown in FIG. 1, there are a plurality of insulating structures 16. The plurality of insulating structures 16 are disposed along the horizontal direction D1 and the horizontal direction D2, and are spaced apart from each other. Therefore, the gate material stack 12 is divided into a plurality of first portions PD1 and a second portion PD2. The plurality of first portions PD1 extend along the horizontal direction D1, the second portion PD2 extend along the horizontal direction D2, and the plurality of first portions PD1 are disposed at two sides of the second portion PD2. The horizontal direction D1 and the horizontal direction D2 may be perpendicular to each other. That is, the extending direction of the first portion PD1 may be perpendicular to the extending direction of the second portion PD2. In the present disclosure, when an element has an extending direction, it may refer that the element extends along the extending direction, and the element has a maximum length in the extending direction.

Next, as shown in FIG. 3, the mask layer ML2, the gate material stack 12 and the insulating structure 16 are patterned to form gate stacks 18 and insulating stacks 20. Each of the gate stacks 18 includes, from bottom to top, a gate insulating layer 122, a charge storage layer 124, a blocking insulating layer 126, a mask layer ML1 and a mask layer ML2. Each of the insulating stacks 20 includes, from bottom to top, an insulating layer 22 (i.e., a portion of the insulating structure 16) and a mask layer ML2. Two adjacent gate stacks 18 may be disposed adjacent to each other along the horizontal direction D1 (as shown in the left portion of FIG. 3), and may be spaced apart from each other. Two adjacent insulating stacks 20 may be disposed adjacent to each other along the horizontal direction D1 (as shown in the right portion of FIG. 3), and may be spaced apart from each other. In addition, the gate stack 18 and the insulating stack 20 are disposed adjacent to each other along the horizontal direction D2, and the gate stack 18 and the insulating stack 20 may be directly adjacent to each other (herein, directly contact with each other) along the horizontal direction D2. The plurality of gate stacks 18 and the plurality of insulating stacks 20 are staggered along the horizontal direction D2.

Specifically, portions of the mask layer ML2, the gate material stack 12 and the insulating structures 16 may be removed along the horizontal direction D2. For example, a patterned photoresist (not shown) extending along the horizontal direction D2 may be firstly formed on the mask layer ML2. Next, an etching process is performed to remove a portion of the mask layer ML2 exposed from the patterned photoresist and the portions of the mask layer ML1, the blocking insulating layer 126, the charge storage layer 124, the gate insulating layer 122 and the insulating structures 16 below the portion of the mask layer ML2 to form the recessed spaces RS1, RS2 and RS3, so as to obtain the semiconductor device shown in FIG. 3. The recessed spaces RS1, RS2 and RS3 extend along the horizontal direction D2. Furthermore, two gate stacks 18 adjacent to each other along the horizontal direction D1 are spaced apart from each other by the recessed space RS2, and two insulating stacks 20 adjacent to each other along the horizontal direction D1 are spaced apart from each other by the recessed space RS2. At this stage, the gate insulating layer 122 is only partially removed in the vertical direction D3, so that the top surface 101 of the substrate 10 corresponding to the recessed spaces RS1, RS2 and RS3 is covered by the gate insulating layer 122 and is not exposed from the gate insulating layer 122.

Next, as shown in FIG. 4, a spacer 23 is formed on the outer side surfaces 184 and the top surfaces 181 of the gate stacks 18 and the outer side surfaces 204 and the top surfaces 201 of the insulating stacks 20, wherein the spacer 23 completely covers the outer side surfaces 184 of the gate stacks 18 and the outer side surfaces 204 of the insulating stacks 20, and the spacer 23 partially covers the top surfaces 181 of the gate stacks 18 and the top surfaces 201 of the insulating stacks 20. The spacer 23 may be a single-layer structure or a multi-layer structure. The material of the spacer 23 may include nitrides, oxides or a combination thereof, such as silicon oxide, silicon nitride, silicon oxynitride or silicon carbide nitride (SiCN).

For example, a spacer material may be formed to blanketly cover the substrate 10 by a deposition process, wherein the spacer material covers the gate stacks 18, the insulating stacks 20, and the portions of the gate insulating layer 122 and the insulating structures 16 not covered by the gate stacks 18 and the insulating stacks 20. Next, an etching back process is performed to remove a portion of the spacer material, so that the portions of the gate insulating layer 122 and the insulating structures 16 not covered by the gate stacks 18 and the insulating stacks 20 are exposed, and the thickness of the spacer material on the gate stacks 18 and the insulating stacks 20 is reduced. Afterwards, the spacer material on the inner side surfaces 183 of the gate stacks 18 and the inner side surfaces 203 of the insulating stacks 20 are removed, the spacer material on the top surfaces 181 of the gate stacks 18 and the top surfaces 201 of the insulating stacks 20 are partially removed, and the gate insulating layer 122 between two gate stacks 18 and between two insulating stacks 20 (i.e., the gate insulating layer 122 located below the recessed space RS2) is removed by semiconductor processes, such as lithography process and etching process, so as to obtain the semiconductor device shown in FIG. 4.

At this stage, the top surface 101 of the substrate 10 located below the recessed space RS2 is exposed, and the gate insulating layer 122 located outside the spacer 23 on the outer side surfaces 184 of the two gate stacks 18 (i.e., the gate insulating layer 122 located below the recessed spaces RS1 and RS3) is not completely removed. Therefore, the top surface 101 of the substrate 10 located outside the spacer 23 on the outer side surfaces 184 of the two gate stacks 18 (i.e., the top surface 101 of the substrate 10 located below the recessed spaces RS1 and RS3) is covered by the gate insulating layer 122 and is not exposed.

Next, as shown in FIG. 5, an ion implantation process P1 is performed to form a doped region 24 in the substrate 10 between the two gate stacks 18 and between the two insulating stacks 20 (i.e., the substrate 10 located below the recessed space RS2). The doped region 24, for example, may serve as a source line of the semiconductor device 1 formed later.

The conductivity type of the doped region 24 may be determined by the dopants thereof. For example, the doped region 24 may be doped with N-type impurities, such as arsenic, phosphorus, etc., and thus has the first conductivity type. As another example, the doped region 24 may be doped with P-type impurities, such as boron, indium, etc., and thus has the second conductivity type. The conductivity type of the doped region 24 is different from the conductivity type of the aforementioned well region.

Before performing the ion implantation process P1, a protective layer 30 may be formed to blanketly cover the substrate 10. The protective layer 30 covers the gate stacks 18, the insulating stacks 20, and the portions of the gate insulating layer 122, the insulating structures 16 and the substrate 10 not covered by the gate stacks 18 and the insulating stacks 20. Afterward, a patterned photoresist 32 is formed on the substrate 10. The patterned photoresist 32 mainly exposes the region between two gate stacks 18 and the region between two insulating stacks 20, so that the remaining regions will not be implanted with ions by the ion implantation process P1. With the protective layer 30, the region where the ion implantation process P1 is performed may be protected, so that the region can be prevented from being seriously damaged by the ion bombardment of the ion implantation process P1.

The method for forming the protective layer 30 may include forming a first protective layer 26 and a second protective layer 28. For example, a thermal oxidation process may be firstly performed, the exposed portion of the substrate 10 (i.e., the portion of the substrate 10 corresponding to the recessed space RS2) is oxidized to obtain an oxide layer as the first protective layer 26. For example, the thermal oxidation process may be performed in an oxygen-containing environment. The oxygen-containing environment may be achieved by introducing oxygen or oxygen-containing gas (such as water vapor) into the process chamber of the thermal oxidation process. The thermal oxidation process may include an in-situ steam generation (ISSG) oxidation process, a wet furnace tube oxidation process, or a dry furnace tube oxidation process, but not limited thereto. During the thermal oxidation process, oxygen atoms in the oxygen-containing gas enter the substrate 10 and combine with the silicon in the substrate 10, so that the surface layer of the substrate 10 corresponding to the recessed space RS2 is oxidized to form the first protective layer 26. Therefore, after the thermal oxidation process, the portion 101a of the top surface 101 of the substrate 10 corresponding to the recessed space RS2 is lowered, and the top surface (not labeled) of the first protective layer 26 is higher than the top surface 101 of the substrate 10 before the thermal oxidation process (see FIG. 4). The bottom surface (not labeled) of the first protective layer 26 is lower than the top surface 101 of the substrate 10 before the thermal oxidation process. Next, a deposition process is performed to form the second protective layer 28 to blanketly cover the substrate 10. The material of the first protective layer 26 may include an oxide, such as silicon oxide. The material of the second protective layer 28 may include an oxide, such as silicon oxide, but not limited thereto. The portions of the first protective layer 26 connected with the gate stacks 18 are formed with bird's beak structures (not labeled). Therefore, the first protective layer 26 has a thickness changing gradually in the horizontal direction D1. For example, the thickness of the first protective layer 26 from one of the gate stacks 18 (herein, the gate stack 18 at the left side) to another one of the gate stacks 18 (herein, the gate stack 18 at the right side) along the horizontal direction D1 is firstly increased and then decreased. The thickness of the second protective layer 28 is substantially the same.

Next, as shown in FIG. 6, with the protection of the patterned photoresist 32, the etching process P2 is performed to remove portions of the protective layer 30 and the insulating layers 22 (i.e., portions of the insulating structures 16), so as to form a widened recess 34 between two insulating stacks 20. For example, the etching process P2 may include a first etching step and a second etching step. The first etching step is firstly performed to remove a portion of the protective layer 30. Next, the second etching step is performed to remove portions of the insulating layers 22 (i.e., portions of the insulating structures 16). With the second etching step, the portions of the insulating layers 22 are removed, so that the portion of the recessed space RS2 located between the two insulating stacks 20 is widened to form the widened recess 34, and the portion of the recessed space RS2 located between the two gate stacks 18 is maintain. The widened recess 34 is located between the two insulating layers 22 of the two insulating stacks 20 and below the mask layer ML2 of the two insulating stacks 20, and is communicated with the original recessed space RS2. The widened recess 34 has a curve side surface 343. Afterward, the patterned photoresist 32 is removed. In some embodiments, the patterned photoresist 32 is consumed when performing the first etching step to remove the protective layer 30. The patterned photoresist 32 may be completely consumed when the first etching step is finished by controlling the etching conditions.

The second etching step may be a wet etching process. For example, the portions of the insulating layers 22 may be removed by an etching solution. The etching solution may include a buffered oxide etchant (BOE) or a dilute hydrofluoric acid (DHF). According to an embodiment of the present disclosure, the second etching step may be performed with the BOE as the etching solution at the room temperature for 100 seconds to 110 seconds. According to another embodiment of the present disclosure, the second etching step may be performed with the DHF as the etching solution at the room temperature for 165 seconds to 195 seconds. According to an embodiment of the present disclosure, the BOE may be a mixture of ammonium fluoride (NH₄F) with a concentration of 40 wt % and hydrofluoric acid (HF) with a concentration of 49 wt %, and a volume ratio of the ammonium fluoride to the hydrofluoric acid may be 6 to 1. The DHF may be a mixture of deionized water and hydrofluoric acid with a concentration of 49 wt %, and a volume ratio of the deionized water to the hydrofluoric acid may be 50 to 1.

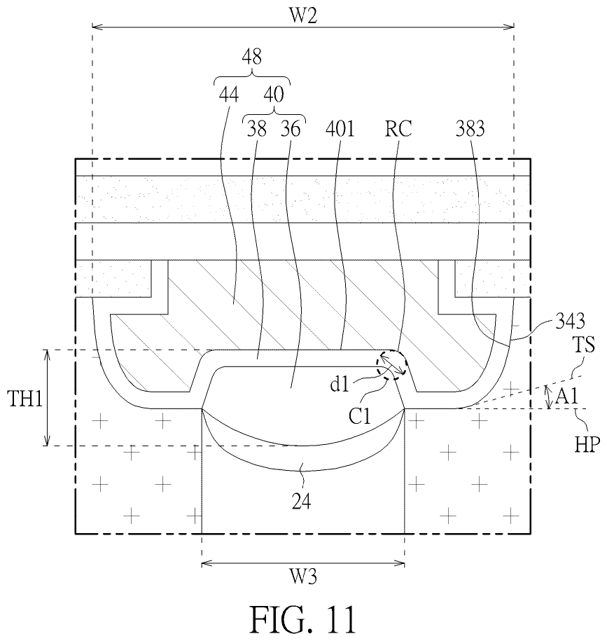

Next, as shown in FIG. 7, a cleaning process P3 may be performed to remove foreign materials such as particles on the semiconductor device. The cleaning process P3 may be performed with a SC1 solution as the cleaning solution at the room temperature for a predetermined time. The aforementioned predetermined time may be, for example, 50 seconds to 65 seconds, or 58 seconds to 60 seconds. The aforementioned room temperature may be, for example, 20° C. to 35° C., or may be 25° C. to 27° C. The SC1 solution may be a mixture of ammonium hydroxide (NH₄OH), hydrogen peroxide (H₂O₂) and deionized water, and the volume ratio of the ammonium hydroxide, the hydrogen peroxide and the deionized water may be, for example, 1:2:50, but not limited thereto. The proportion of the ingredients of the SC1 solution may be adjusted according to actual needs. Compared with using the SC1 solution as the cleaning solution at a higher temperature such as 70° C., the cleaning process P3 of the present disclosure is performed at the room temperature, it is beneficial to reduce the loss degree of the substrate 10 in the cleaning process P3, which is beneficial to enhance the thickness of the gate insulating layer 40 (see FIG. 8) formed later, and is beneficial to allow the gate insulating layer 40 to have a rounding corner RC (see FIG. 11).

In the present disclosure, by controlling the solutions and parameters of the second etching step of the etching process P2 and the subsequent cleaning process P3, it is beneficial to allow the curve side surface 343 to have a smaller inclined angle A1, and is beneficial to allow the gate insulating layer 40 formed later to have a thicker thickness (such as the maximum thickness TH1 shown in FIG. 11) and a rounding corner RC (see FIG. 11), which is beneficial to enhance the breakdown voltage, so as to improve the properties of the semiconductor device 1 formed later. For this part, references may be made to the relevant description of FIG. 11.

Next, as shown in FIG. 8, a gate insulating layer 40 is formed on the doped region 24, the inner side surfaces 183 and the top surfaces 181 of the two gate stacks 18, and the inner side surfaces 203 and the top surfaces 201 of the two insulating stacks 20. Forming the gate insulating layer 40 may include forming a first sub-layer 36 and a second sub-layer 38. For example, the exposed portion of the substrate 10 (i.e., the portion of the substrate 10 corresponding to the recessed space RS2 and the widened recess 34) may be oxidized through a thermal oxidation process to obtain an oxide layer as the first sub-layer 36. For the thermal oxidation process, references may be made to the above description and are not repeated herein. After the thermal oxidation process, the portion 101b of the top surface 101 of the substrate 10 corresponding to the recessed space RS2 is lower than the portion 101a (refer to FIG. 7) before the thermal oxidation process. The top surface (not labeled) of the first sub-layer 36 is higher than the portion 101a before the thermal oxidation process, and the bottom surface (not labeled) of the first sub-layer 36 is also lower than the portion 101a before the thermal oxidation process. Next, a deposition process is performed to form the second sub-layer 38 to blanketly cover the substrate 10. The material of the first sub-layer 36 may include oxides, such as silicon oxide, and the material of the second sub-layer 38 may include oxides, such as silicon oxide, but not limited thereto.

Next, semiconductor processes, such as lithography process and etching process, may be performed to completely remove the protective layer 30, the second sub-layer 38 on the protective layer 30, as well as the gate insulating layer 122 located below the recessed spaces RS1 and RS3. The remaining second sub-layer 38 covers the first sub-layer 36, the inner side surfaces 183 of the gate stacks 18, the inner side surfaces 203 of the insulating stacks 20 and partially covers the top surfaces 181 of the gate stacks 18 and the top surfaces 201 of the insulating stacks 20. The portions of the first sub-layer 36 connected with the gate stacks 18 are formed with bird's beak structures (not labeled). Therefore, the first sub-layer 36 has a thickness changing gradually in the horizontal direction D1. For example, the thickness of the first sub-layer 36 from one of the gate stacks 18 (herein, the gate stack 18 at the left side) to another one of the gate stacks 18 (herein, the gate stack 18 at the right side) along the horizontal direction D1 is firstly increased and then decreased. The thickness of the second sub-layer 38 is substantially the same.

Afterward, a gate insulating layer 42 is formed on the substrate 10 below the recessed spaces RS1 and RS3. The material of the gate insulating layer 42 may include dielectric materials, such as silicon oxide, silicon nitride, silicon oxynitride, high dielectric constant materials, other non-conductive materials, or a combination thereof. Herein, the material of the gate insulating layer 42 exemplarily includes silicon oxide, and the gate insulating layer 42 is formed by a thermal oxidation process. Therefore, the gate insulating layer 42 is not formed on the insulating structure 16 located below the recessed spaces RS1 and RS3.

Next, please refer to FIG. 9 and FIG. 10. FIG. 10 shows schematic cross-sectional views taken along line A-A′ and line B-B′ in FIG. 9. For the sake of conciseness, some elements are omitted in FIG. 9 compared with FIG. 10. FIG. 9 mainly shows the insulating structures 16, the charge storage layers 124 of the gates 46, the gate conductive layer 44 of the gate 48, the gate conductive layers 44 of the gates 50, the recess spaces RS1 and the widened recesses 34, and other elements are omitted.

First, a gate conductive material may be formed to blanketly cover the substrate 10 by a deposition process, and the gate conductive material is filled into the recessed spaces RS1, RS2, RS3 and the widened recess 34. Afterward, a planarization process is performed to remove a portion of the gate conductive material, a portion of the mask layer ML2 and a portion of the gate insulating layer 40, so that the top surface of the gate conductive material is aligned with the top surface of the remaining mask layer ML2 and the top surface of the remaining gate insulating layer 40, so as to form the gate conductive layer 44 and lower the heights of the gate stacks 18 and the insulating stacks 20. Thereby, the fabrication of the gates 46 and the gate 48 is completed. The material of the gate conductive layer 44 may include conductive materials, such as doped polycrystalline silicon, doped amorphous silicon, metal or metal compounds.

Afterward, the gate conductive layer 44 and the gate insulating layer 42 located in the recessed spaces RS1 and RS3 may be removed by semiconductor processes, such as lithography process and etching process, so as to complete the fabrication of the gates 50. Afterward, a spacer 52 may be formed on the outer side surfaces 503 of the gates 50, and an ion implantation process may be performed to form doped regions 54 in the portion of the substrate 10 exposed from the recessed spaces RS1 and RS3. The conductivity type of the doped regions 54 may be identical to that of the doped region 24, and may be different from that of the well region.

Afterward, a dielectric layer 56 may be formed to surround the spacer 52 and fill into the remaining spaces of the recessed spaces RS1 and RS3 by a deposition process, a planarization process, etc. Next, mask layers ML3, ML4, and ML5 may be optionally formed on the substrate 10. Thereby, the fabrication of the semiconductor device 1 is completed. The material of the spacer 52 may include nitrides, oxides, or a combination thereof, such as silicon oxide, silicon nitride, silicon oxynitride, or silicon carbide nitride (SiCN). The material of the dielectric layer 56 may include dielectric materials, such as silicon oxide, tetraethoxysilane (TEOS), or silicon nitride, but not limited thereto. The mask layers ML3, ML4, and ML5, for example, may be used to allow the top surface of the device region 11 to be aligned with the top surfaces of other regions (not shown). The materials of the mask layers ML3, ML4 and ML5 may independently include silicon oxide, silicon nitride, silicon carbide and/or silicon oxynitride, but not limited thereto.

The aforementioned film layers, such as the gate insulating layer 122, the charge storage layer 124, the blocking insulating layer 126, the insulating structure 16, the spacers 23 and 52, the protective layer 30, the gate insulating layer 40 and the mask layers ML1, ML2, ML3, ML4 and ML5, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 9 to FIG. 11. FIG. 9 shows a schematic top view of the semiconductor device 1 according to an embodiment of the present disclosure. FIG. 10 shows schematic cross-sectional views taken along line A-A′ and line B-B′ in FIG. 9. FIG. 11 is an enlarged view of a portion X of the semiconductor device 1 shown in FIG. 10. The semiconductor device 1 includes the doped region 24, the gate 48 and the insulating structure 16. The gate 48 extends along the horizontal direction D2 on the doped region 24. The insulating structure 16 is disposed at a side of the gate 48 along the horizontal direction D1. The insulating structure 16 includes the curve side surface 343 directly contacting the gate 48, and the curve side surface 343 has an inclined angle A1 less than 45 degrees. The aforementioned inclined angle A1 may be an included angle between the tangential plane TS of the bottom of the curve side surface 343 and the horizontal plane HP. For example, the bottom of the curve side surface 343 may be a position inclined relative to the horizontal plane HP at the bottommost of the curve side surface 343.

Specifically, the semiconductor device 1 may include a plurality of memory units (not labeled). Each of the memory units may include a gate 48, two gates 46, two gates 50, a doped region 24, two doped regions 54 and a channel region 58. The doped region 24, the doped regions 54 and the channel region 58 are located in the substrate 10, and the channel region 58 is located between the doped region 24 and the doped region 54. The gate 46 and the gate 50 are disposed on the channel region 58, and the gate 48 is disposed on the doped region 24.

As shown in FIG. 9, the gate 48 extends along the horizontal direction D2, the gate 46 extends along the horizontal direction D1, and the gate 50 extends along the horizontal direction D2. Each of the gates 46 is disposed at a side of the gate 48 along the horizontal direction D1, and two gates 46 are symmetrically disposed at two sides of the gate 48 along the horizontal direction D1. Each of the gates 50 is disposed at a side of the gate 46 away from the gate 48 along the horizontal direction D1, and two gates 50 are symmetrically disposed at two sides of the gate 48 along the horizontal direction D1. The gate 46 and the insulating structure 16 are adjacent to each other in the horizontal direction D2. Furthermore, the plurality of gates 46 and the plurality of insulating structures 16 of the plurality of memory units are staggered in the horizontal direction D2. The insulating structures 16 can provide the electrical isolation function between the plurality of memory units.

The gate 48 may be an erase gate, the gate 46 may be a memory gate such as a floating gate, and the gate 50 may be a selective gate. The doped region 24 may serve as a source region, and the doped region 54 may serve as a drain region, wherein the doped region 24 is shared by the two gates 46 disposed along the horizontal direction D1. In some embodiments, the gate 50 may serve as a word line, and the doped region 24 may serve as a source line.

The gate 48 has a first width W1 and a second width W2 in the horizontal direction D1, wherein the first width W1 corresponds to the gate 46, the second width W2 corresponds to the insulating structure 16, and the second width W2 is greater than the first width W1. As shown in FIG. 11, in the horizontal direction D1, the second width W2 of the gate 48 is greater than the width W3 of the doped region 24.

The gate 46 may include the gate insulating layer 122, the charge storage layer 124, the blocking insulating layer 126, the mask layer ML1 and the mask layer ML2 from bottom to top. The gate 50 may include the gate insulating layer 42 and the gate conductive layer 44 from bottom to top. The gate 48 may include the gate insulating layer 40 and the gate conductive layer 44 from outside to inside (or from bottom to top). The gate insulating layer 40 may include the first sub-layer 36 and the second sub-layer 38. The first sub-layer 36 may directly contact the doped region 24, and the first sub-layer 36 does not directly contact the insulating structure 16. The second sub-layer 38 may directly contact the insulating structure 16 (which includes directly contacting the curve side surface 343 of the insulating structure 16), and the second sub-layer 38 does not directly contact the doped region 24.

As shown in FIG. 11, the gate insulating layer 40 may include the convex surface 401, and the convex surface 401 may include the rounding corner RC located at the periphery of the convex surface 401. The rounding corner RC may define an inscribed circle C1. According to an embodiment of the present disclosure, a diameter d1 of the inscribed circle C1 may be greater than or equal to 14 nanometers (nm) and less than or equal to 18 nm. The gate insulating layer 40 may include the curve side surface 383 disposed on the curve side surface 343. The curve side surface 383 directly contacts with the curve side surface 343. The gate insulating layer 40 may have a maximum thickness TH1 corresponding to the convex surface 401, wherein the maximum thickness TH1 may be greater than or equal to 260 angstroms and less than or equal to 340 angstroms. For example, the maximum thickness TH1 may be 300 angstroms. For other details about the semiconductor device 1, references may be made to the above description and are not repeated herein.

According to the present disclosure, a method for fabricating a semiconductor device includes steps as follows. An insulating structure is formed in a substrate, wherein the substrate includes a portion disposed adjacent to the insulating structure. A doped region is formed in the portion of the substrate. A portion of the insulating structure is removed to form a first curve side surface. A first gate extending along a first direction is formed on the doped region, wherein the insulating structure is disposed at a side of the first gate along a second direction, the first curve side surface directly contacts the first gate, and the first curve side surface has an inclined angle less than 45 degrees.

In some embodiments, the method for fabricating the semiconductor device may further include cleaning the first curve side surface and the doped region with a mixture of ammonium hydroxide, hydrogen peroxide and deionized water at the room temperature.

In some embodiments, the portion of the insulating structure may be removed by an etching solution, and the etching solution may include a buffered oxide etchant or a dilute hydrofluoric acid.

In some embodiments, the method for fabricating the semiconductor device may further include the following steps. A protective layer is formed on the portion of the substrate. The doped region is formed in the portion of the substrate. The protective layer is removed.

In some embodiments, forming the first gate may include steps as follows. A gate insulating layer is formed on the doped region and the first curve side surface. A gate conductive layer is formed on the gate insulating layer, wherein the gate insulating layer includes a convex surface.

In some embodiments, forming the gate insulating layer may include steps as follows. A first sub-layer directly contacting the doped region is formed. A second sub-layer directly contacting the insulating structure is formed.

In some embodiments, the method for fabricating a semiconductor device may further include steps as follows. A second gate is formed at the side of the first gate along the second direction, wherein the second gate and the insulating structure are adjacent to each other in the first direction.

Compared with the prior art, in the present disclosure, a portion of the insulating structure is removed by an etching process, so that the insulating structure disposed at a side of the first gate is configured with a first curve side surface. Moreover, the solutions and parameters of the etching process and the subsequent cleaning process are controlled to allow the first curve side surface to have a smaller inclined angle, and preferably to allow the gate insulating layer formed later to have a thicker thickness and a rounding corner, which is beneficial to enhance the breakdown voltage, and improve the properties of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a doped region disposed in a substrate;
a first gate extending along a first direction on the doped region; and
an insulating structure disposed at a side of the first gate along a second direction, wherein the insulating structure comprises a first curve side surface directly contacting the first gate, and the first curve side surface has an inclined angle less than 45 degrees.

2. The semiconductor device of claim 1, wherein the first gate comprises a gate insulating layer and a gate conductive layer from outside to inside, and the gate insulating layer comprises a convex surface.

3. The semiconductor device of claim 2, wherein the convex surface has a rounding corner.

4. The semiconductor device of claim 3, wherein the rounding corner defines an inscribed circle, and a diameter of the inscribed circle is greater than or equal to 14 nm and less than or equal to 18 nm.

5. The semiconductor device of claim 2, wherein the gate insulating layer further comprises a first sub-layer and a second sub-layer, the first sub-layer directly contacts the doped region, and the second sub-layer directly contacts the insulating structure.

6. The semiconductor device of claim 2, wherein the gate insulating layer further comprises a second curve side surface disposed on the first curve side surface.

7. The semiconductor device of claim 1, wherein a width of the first gate in the second direction is greater than a width of the doped region in the second direction.

8. The semiconductor device of claim 1, further comprising:
a second gate disposed at the side of the first gate along the second direction, wherein the second gate and the insulating structure are adjacent to each other in the first direction.

9. The semiconductor device of claim 8, wherein the first gate is an erase gate, and the second gate is a memory gate.

10. The semiconductor device of claim 8, wherein in the second direction, the first gate has a first width corresponding to the second gate and a second width corresponding to the insulating structure, and the second width is greater than the first width.

11. A method for fabricating a semiconductor device, comprising:
forming an insulating structure in a substrate, wherein the substrate comprises a portion disposed adjacent to the insulating structure;
forming a doped region in the portion of the substrate;
removing a portion of the insulating structure to form a first curve side surface; and
forming a first gate extending along a first direction on the doped region, wherein the insulating structure is disposed at a side of the first gate along a second direction, the first curve side surface directly contacts the first gate, and the first curve side surface has an inclined angle less than 45 degrees.

12. The method of claim 11, further comprising:
cleaning the first curve side surface and the doped region with a mixture of ammonium hydroxide, hydrogen peroxide and deionized water at a room temperature.

13. The method of claim 11, wherein the portion of the insulating structure is removed by an etching solution, and the etching solution comprises a buffered oxide etchant or a dilute hydrofluoric acid.

14. The method of claim 11, further comprising:
forming a protective layer on the portion of the substrate;
forming the doped region in the portion of the substrate; and
removing the protective layer.

15. The method of claim 11, wherein forming the first gate comprises:
forming a gate insulating layer on the doped region and the first curve side surface; and
forming a gate conductive layer on the gate insulating layer, wherein the gate insulating layer comprises a convex surface.

16. The method of claim 15, wherein forming the gate insulating layer comprises:
forming a first sub-layer directly contacting the doped region; and
forming a second sub-layer directly contacting the insulating structure.

17. The method of claim 15, wherein the gate insulating layer further comprises a second curve side surface disposed on the first curve side surface.

18. The method of claim 11, wherein a width of the first gate in the second direction is greater than a width of the doped region in the second direction.

19. The method of claim 11, further comprising:
forming a second gate at the side of the first gate along the second direction, wherein the second gate and the insulating structure are adjacent to each other in the first direction.

20. The method of claim 19, wherein the first gate is an erase gate, and the second gate is a memory gate.
